(19) United States
(12) Patent Application Publication
(10) Pub. No.: US 2012/0251705 A1
(43) Pub. Date: Oct. 4, 2012

(54) TEMPERATURE CONTROLLING METHOD AND PLASMA PROCESSING SYSTEM

(75) Inventor: Tatsuo MATSUDO, Nirasaki City (JP)

(73) Assignee: TOKYO ELECTRON LIMITED, Tokyo (JP)

(21) Appl. No.: 13/435,673

(22) Filed: Mar. 30, 2012

Related U.S. Application Data
(60) Provisional application No. 61/537,711, filed on Sep. 22, 2011.

(30) Foreign Application Priority Data
Mar. 30, 2011 (JP) 2011-074993

(51) Int. Cl. C23C 16/52; C23C 16/448

(52) U.S. Cl. 427/8; 118/712

(57) ABSTRACT

In order to control a temperature of a wafer with high accuracy, there is provided a temperature controlling method including retrieving a result of measuring a kind of a film formed on a rear surface of the wafer; selecting a temperature of the wafer corresponding to an electric power supplied to process the wafer and the kind of the film formed on the rear surface of the wafer, which is the measurement result, from a first database, in which the electric power supplied to a chamber, the kind of the film formed on the rear surface of the wafer, and the temperature of the wafer are stored to be linked to one another; and adjusting the temperature of the wafer based on the selected temperature of the wafer.

CROSS-REFERENCE TO RELATED PATENT APPLICATIONS

This application claims the benefit of Japanese Patent Application No. 2011-074993, filed on Mar. 30, 2011, in the Japan Patent Office and U.S. Patent Application Ser. No. 61/537,711, filed on Sep. 22, 2011, in the United States Patent and Trademark Office, the disclosure of which are incorporated herein in their entireties by reference.

### BACKGROUND OF THE INVENTION

1. Field of the Invention

The present invention relates to a temperature controlling method and a plasma processing system, and more particularly, to a temperature controlling method when a processing object is processed.

2. Description of the Related Art

When etching or film formation is performed on, for example, a semiconductor wafer, controlling of a temperature of the semiconductor wafer is relevant to a film forming rate or an etching rate of the semiconductor wafer, thereby affecting features of a film or a shape of a hole formed in the wafer. Therefore, it is important to improve accuracy of controlling the temperature of the wafer in order to improve processing accuracy of the wafer, yield, and productivity of the wafer.

Thus, a method of measuring a temperature of a wafer by using a resistance thermometer, a fluorescent thermometer for measuring a temperature of a rear surface of the wafer, or the like has been conventionally suggested. Patent Document 1 discloses a method of measuring a temperature of a wafer based on an interference state between measuring light reflected by the wafer and reference light reflected by a driving mirror, by using a light source, a splitter for dividing light emitted from the light source into the measuring light and the reference light, and a driving mirror for reflecting the reference light from the splitter and changing an optical path length of the reference light.

A measured temperature of the wafer varies depending on a temperature of a coolant flowing in a cooling tube provided in a susceptor, a temperature of a heater provided in the susceptor, and a pressure of a heat transferring gas flowing between the wafer and the susceptor. Therefore, in order to adjust the temperature of the wafer to a desired level based on relations between the measured temperature of the wafer, the temperature of the coolant, the temperature of the heater, and the pressure of the heat transferring gas, it is determined how the temperature of the coolant, the temperature of the heater, and the pressure of the heat transferring gas are controlled.

However, the measured temperature of the wafer may be changed according to a film formed on a rear surface of the wafer. Therefore, the temperature of the wafer may not be adjusted to the desired level by only controlling the temperature of the coolant, the temperature of the heater, and the pressure of the heat transferring gas, without considering a state of the rear surface of the wafer. Accordingly, expected processing results may not be obtained.

(Patent Document 1) Japanese Laid-open Patent Publication No. 2010-199526

### SUMMARY OF THE INVENTION

The present invention provides a temperature controlling method capable of controlling a temperature of a processing object with high accuracy, and a plasma processing system.

According to an aspect of the present invention, there is provided a method of controlling temperature, the method including: retrieving a result of measuring a kind of a film formed on a rear surface of a processing object; selecting a temperature of the processing object corresponding to an electric power supplied to process the processing object and the kind of the film formed on the rear surface of the processing object, which is the measurement result, from a first database, in which the electric power supplied to a chamber, the kind of the film formed on the rear surface of the processing object, and the temperature of the processing object are stored to be linked to one another; and adjusting the temperature of the processing object based on the selected temperature of the processing object.

The adjusting of the temperature of the processing object may include controlling a cooling mechanism and a heating mechanism based on the selected temperature of the processing object.

The selecting of the temperature of the processing object may include selecting a pressure of a heat transferring gas corresponding to the selected temperature of the processing object from a second database, in which the pressure of the heat transferring gas flowing on the rear surface of the processing object and the temperature of the processing object are stored to be linked to each other, and the adjusting of the temperature may include adjusting the heat transferring gas flowing on the rear surface of the processing object based on the selected pressure of the heat transferring gas.

The method may further include measuring the temperature of the processing object according to the power supplied in the chamber by using a non-contact temperature with respect to the processing objects in which a kind of film formed on the rear surface thereof is different, and accommodating the measured temperature of the processing object in linkage with the kind of the film formed on the rear surface and the power in the first database.

According to another aspect of the present invention, there is provided a plasma processing system which includes a chamber in which a plasma process is performed on a processing object, the plasma processing system including: a retrieving unit which obtains a result of measuring a kind of a film formed on a rear surface of the processing object; a selection unit which selects a temperature of the processing object corresponding to an electric power supplied to process the processing object and the kind of the film formed on the rear surface of the processing object, which is the measurement result, from a first database, in which the electric power supplied to a chamber, the kind of the film formed on the rear surface of the processing object, and the temperature of the processing object are stored to be linked to one another; and an adjusting unit which adjusts the temperature of the processing object based on the selected temperature of the processing object.

The plasma processing system may further include a cooling mechanism and a heating mechanism provided in a susceptor, on which the processing object is held, and the adjusting unit may control the cooling mechanism and the heating mechanism based on the selected temperature of the processing object.

The selection unit may select a pressure of a heat transferring gas corresponding to the selected temperature of the processing object from a second database, in which the pressure of the heat transferring gas flowing on the rear surface of the processing object and the temperature of the processing object are stored to be linked to each other, and the adjusting unit may adjust the heat transferring gas flowing on the rear surface of the processing object based on the selected pressure of the heat transferring gas.

The plasma processing system may further include a heat transferring gas supply mechanism provided in the susceptor, on which the processing object is held, wherein the adjusting unit may control the heat transferring gas supply mechanism based on the selected pressure of the heat transferring gas.

The plasma processing system may further include: an alignment mechanism which determines a location of the processing object; and a measurement unit which optically measures the kind of the film formed on the rear surface of the processing object that is held on the alignment mechanism.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram showing an overall plasma processing system according to an embodiment of the present invention;

FIG. 2 is a longitudinal-sectional view of a plasma processing apparatus according to an embodiment of the present invention;

FIG. 3 is a functional block diagram of a controlling device;

FIG. 4 is a graph showing a relation between a kind of a film formed on a rear surface and a temperature variation according to an embodiment of the present invention;

FIG. 5 is a diagram showing a first database according to an embodiment of the present invention;

FIG. 6 is a diagram showing a second database according to an embodiment of the present invention;

FIG. 7 is a flowchart for explaining a temperature controlling method according to an embodiment of the present invention;

FIG. 8 is a flowchart for explaining a temperature controlling method according to a modified example of an embodiment of the present invention;

FIG. 9 is a diagram showing an example of thermometer according to an embodiment of the present invention; and

FIGS. 10A and 10B are graphs for explaining frequency analyzing and a temperature measuring method according to an embodiment of the present invention.

### DETAILED DESCRIPTION OF THE INVENTION

Hereinafter, the present invention will be described in detail by explaining exemplary embodiments of the invention with reference to the attached drawings. Like reference numerals in the drawings denote like elements.

Hereinafter, components of a plasma processing system, a plasma processing apparatus, and a controlling apparatus according to embodiments of the present invention will be described. After that, a temperature controlling method according to an embodiment of the present invention and a temperature controlling according to a modified example of an embodiment of the present invention will be described in the stated order.

[Overall Configuration of Plasma Processing System]

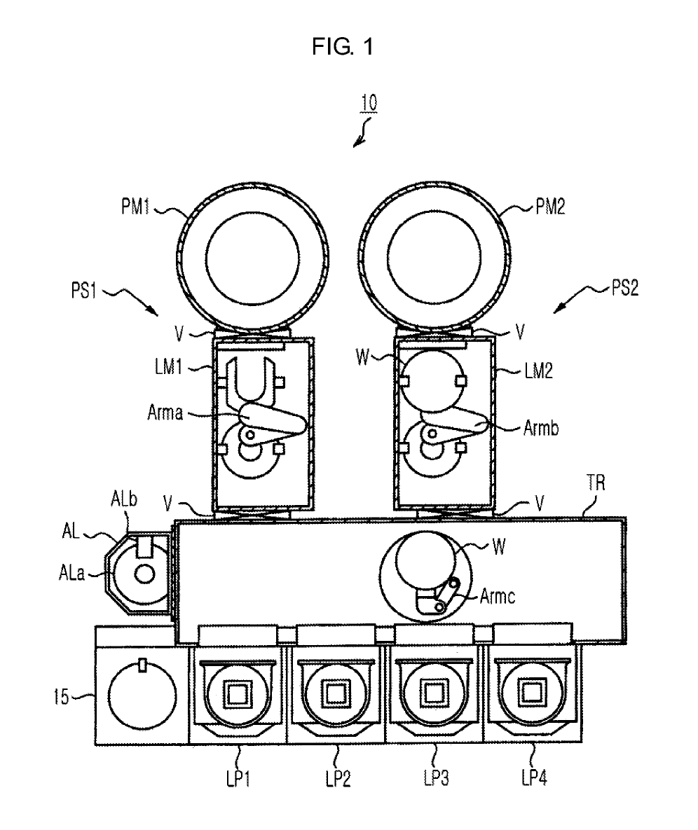

First, an overall configuration of a plasma processing system according to an embodiment of the present invention will be described with reference to FIG. 1. FIG. 1 is a block diagram showing the plasma processing system according to the present embodiment.

A plasma processing system 10 includes a first process ship PS1, a second process ship PS2, a transfer unit TR, an alignment mechanism AL, and load ports LP1 through LP4.

The first process ship PS1 includes a process module PM1 and a load lock module LM1. The second process ship PS2 includes a process module PM2 and a load lock module LM2. Each of the load lock modules LM1 and LM2 transfers a wafer W held by a transfer arm Arma or Armb between each of the process modules PM1 and PM2 and the transfer unit TR while adjusting an internal pressure by opening/closing gate valves V provided at opposite ends of each of the load lock modules LM1 and LM2.

The load ports LP1 through LP4 are provided on a side portion of the transfer unit TR. A FOUP is placed on each of the load ports LP1 through LP4. In the present embodiment, four load ports LP1 through LP4 are provided; however, the present invention is not limited thereto.

A transfer arm Armc is provided on the transfer unit TR, and the transfer unit TR transfers a desired wafer W received in the load ports LP1 through LP4 by using the transfer arm Armc in communication with the transfer arms Arma and Armb in the load lock modules LM1 and LM2.

The alignment mechanism AL for determining a location of the wafer W is provided on an end of the transfer unit TR. The wafer W is aligned by rotating a rotary table ALa in a state where the wafer W is held thereon and detecting a state of a peripheral portion of the wafer W by using an optical sensor ALb.

Through the above configuration, the wafer W in the FOUP that is placed on each of the load ports LP1 through LP4 is aligned by the aligning mechanism AL via the transfer unit TR, and after that, is transferred to any one of the process ships PS1 and PS2 to be plasma-processed in the process module PM1 or PM2. Then, the wafer W is accommodated in the FOUP again.

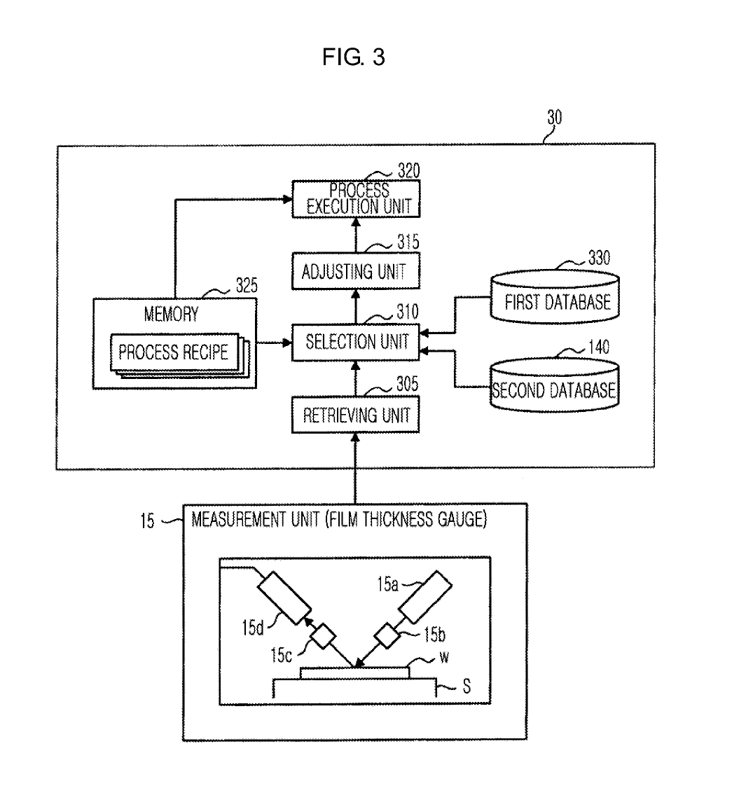

A measurement unit 15 is provided around the alignment mechanism AL. The measurement unit 15 optically measures a kind of a film formed on a rear surface of the wafer W that is held on the alignment mechanism AL. The measurement unit 15 is formed of a spectroscope-type film thickness gauge including a light emitter 15a, a polarizer 15b, an analyzer 15c, and a receiver 15d, as shown in FIG. 3. When the wafer W is held on the alignment mechanism AL, the measurement unit 15 optically measures the kind of the film formed on the rear surface of the wafer W, as follows.

The light emitter 15a outputs white light toward the rear surface of the wafer W, and the polarizer 15b converts the output white light into linearly polarized light and then irradiates the converted light to the rear surface of the wafer W held on a stage S. The analyzer 15c transmits only polarized light having a certain deflection angle among elliptically polarized light reflected by the wafer W. The receiver 15d is formed of, for example, a photo diode or a charged-coupled device (CCD) camera, and receives the polarized light transmitted through the analyzer 15c. As such, the measurement unit 15 optically measures the kind of the film formed on the rear surface of the wafer W from the state of light received by the receiver 15d, for example, by analyzing an interference pattern. If kinds of films that may be detectable are known in advance, the kinds of films may be identified by detecting only a reflectivity of the light.

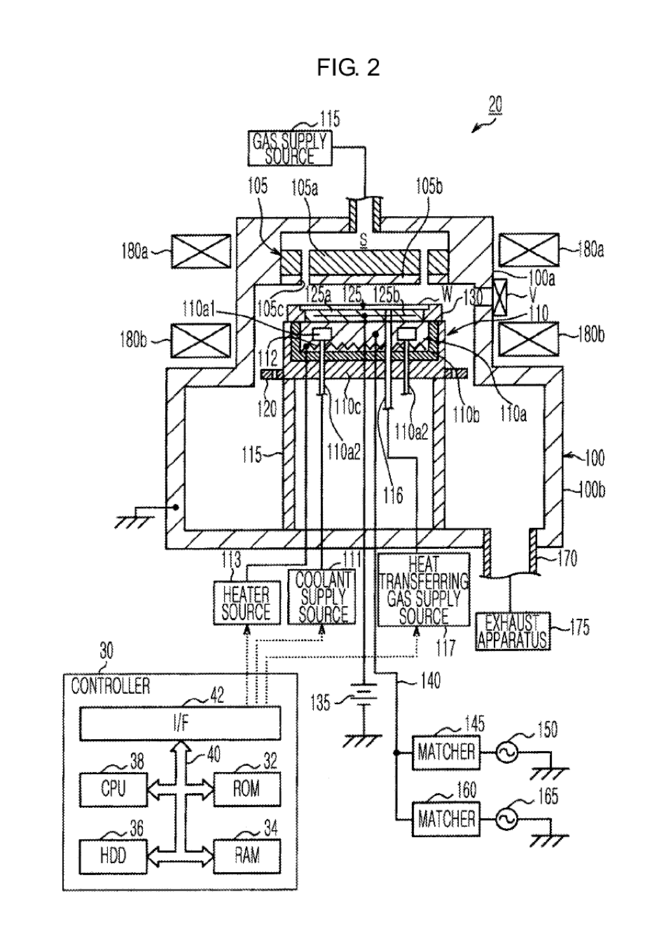

The Information about the kind of the film formed on the rear surface of the wafer W is transferred to a controller 30 shown in FIG. 2. The controller 30 executes a temperature controlling operation according to the kind of the film formed on the rear surface of the wafer W. In addition, the controller 30 selects an optimal process recipe with respect to the kind of the film formed on the rear surface of the wafer W, and controls a plasma process based on the selected process recipe.

[Configuration of Plasma Processing Apparatus]

Next, a configuration of a plasma processing apparatus according to the present embodiment will be described with reference to FIG. 2. FIG. 2 is a longitudinal-sectional view of the plasma processing apparatus according to the present embodiment. Here, a plasma processing apparatus 20 according to the present embodiment is assumed to be an etching apparatus; however, the plasma processing apparatus 20 is not limited thereto, and may be applied to all kinds of plasma processing apparatuses such as a film forming apparatus, an ashing apparatus, or the like, provided that a fine process is performed on the wafer W by using plasma.

The plasma processing apparatus 20 includes a chamber 100, in which the wafer W transferred from one gate valve V is plasma-processed. The chamber 100 consists of an upper cylindrical chamber 100a and a lower cylindrical chamber 100b. The chamber 100 is formed of metal, for example, aluminum, and is grounded.

In the chamber 100, an upper electrode 105 and a lower electrode 110 are arranged to face each other, and accordingly, the upper and lower electrodes 105 and 110 form a pair of parallel flat plate electrodes. The upper electrode 105 includes a base 105a and an insulating layer 105b. The base 105a is formed of metal, for example, aluminum, carbon, titanium, or tungsten.

The insulating layer 105b is formed by spraying alumina or Yttria on a lower surface of the base 105a. A plurality of gas holes 105c are formed in the upper electrode 105 such that the upper electrode 105 may function as a shower plate. That is, a gas supplied from a gas supply source 115 is diffused in a diffusion space S in the chamber 100, and after that, is introduced into the chamber 100 through the plurality of gas holes 105c. The base 105a of the upper electrode 105 may be Si or SiC, and in this case, the insulating layer 105b is not necessary. In addition, a cover formed of quartz may be attached to the base 105a.

The lower electrode 110 functions as a susceptor on which the wafer W is held. The lower electrode 110 includes a base 110a. The base 110a is formed of metal such as aluminum, and is supported by a supporting board 110c via an insulating layer 110b. Accordingly, the lower electrode 110 is in an electrically excited state. In addition, a lower portion of the supporting board 110c is covered by a cover 115. A baffle plate 120 is provided on a lower outer circumference of the supporting board 110c to control flow of a gas.

A coolant chamber 110a1 and coolant introduction tubes 110a2 are provided in the base 110a. The coolant chamber 110a1 is connected to a coolant supply source 111 via the coolant introduction tube 110a2. A coolant supplied from the coolant supply source 111 is introduced through one coolant introduction tube 110a2 to circulate in the coolant chamber 110a1, and then is discharged through another coolant induction tube 110a2. Accordingly, the base 110a is cooled down.

A heater 112 is buried in the base 110a. The heater 12 is connected to a heater source 113. AC electric power supplied from the heater source 113 is applied to the heater 112, and accordingly, the base 110a is heated.

An electrostatic chuck mechanism 125 is provided on an upper surface of the base 110a and the wafer W may be held on the electrostatic chuck mechanism 125. A focus ring 130 formed of, for example, silicon, is provided on an outer circumference of the electrostatic chuck mechanism 125 for maintaining uniformity of plasma. The electrostatic chuck mechanism 125 has a configuration, in which an electrode portion 125b that is a metal sheet member is interposed in an insulating member 125a such as alumina. A DC power source 135 is connected to the electrode portion 125b. A DC voltage output from the DC power source 135 is applied to the electrode portion 125b, and thus, the wafer W is electrostatically adhered to the lower electrode 110.

A heat transferring gas supply pipe 116 penetrates through the lower electrode 110, and a leading edge of the heat transferring gas supply pipe 116 is opened at an upper surface of the electrostatic chuck mechanism 125. The heat transferring gas supply pipe 116 is connected to a heat transferring gas supply source 117. A heat transferring gas supplied from the heat transferring gas supply source 117, for example, a helium gas, flows between the wafer W and the electrostatic chuck mechanism 125. Accordingly, thermal conduction to the base 110a is controlled, thereby adjusting a temperature of the wafer W.

The coolant chamber 110a1 and the coolant introduction tubes 110a2 are an example of a cooling mechanism provided in the susceptor, on which the wafer W is held, and the heater 112 is an example of a heating mechanism provided in the susceptor, on which the wafer W is held. The heat transferring gas supply pipe 116 is an example of a heat transferring gas supply mechanism provided in the susceptor, on which the wafer W is held.

In a temperature controlling method according to a modified example of the present embodiment, which will be described later, a temperature of the base 110a is controlled to a desired temperature by using a cooling mechanism, a heating mechanism, and a heat transferring gas supply mechanism, and thereby a temperature of the wafer W is adjusted.

The base 110a is connected to a radio frequency power source 150 via a matcher 145 that is connected to a power feed rod 140. A gas in the chamber 100 is excited by electric field energy of radio frequency waves output from the radio frequency power source 150, and the wafer W is etched by discharge type plasma generated by the excitation.

The base 110a is also connected to a radio frequency electric power source 165 via a matcher 160 that is connected to the power feed rod 140. Radio frequency waves of, for example, 3.2 MHz, output from the radio frequency electric power source 165 is used as a bias voltage to drag ions to the lower electrode 110.

An exhaust hole 170 is provided in a bottom surface of the chamber 100, and an exhaust apparatus 175 connected to the exhaust hole 170 is driven to maintain an inside of the chamber 100 at a desired vacuum state. Multi-pole ring magnets 180a and 180b are arranged around the upper chamber 100a. In each of the multi-pole ring magnets 180a and 180b, a plurality of magnets formed as anisotropic segment poles are attached to a casing formed as a ring, and the plurality of magnets formed as the anisotropic segment poles are arranged such that polar directions in the plurality of adjacent anisotropic segment pole shaped magnets are inverse to each other. Accordingly, magnetic lines of force are formed between the adjacent segment magnets and a magnetic field is formed only on a peripheral portion of a processing space between the upper electrode 105 and the lower electrode 110, thereby trapping plasma in the processing space. However, the multi-pole ring magnets may not be formed.

[Hardware Configuration of Controller]

Next, a configuration of the controller 30 according to the present embodiment will be described. FIG. 2 shows a hardware configuration of the controller 30. FIG. 3 shows a functional configuration of the controller 30.

As shown in FIG. 2, the controller 30 includes a read only memory (ROM) 32, a random access memory (RAM) 34, a hard disk drive (HDD) 36, a central processing unit (CPU) 38, a bus 40, and an interface (I/F) 42. Commands to each of the components shown in FIG. 3 are executed by an exclusive controlling device or the CPU 38 for executing programs. Programs or various data for executing a temperature controlling method that will be described later are stored in the ROM 32, the RAM 34, or the HDD 36 in advance. The CPU 38 reads necessary program or data from the memory and executes the read program or data to realize functions of the controller 30 shown in FIG. 3.

[Functional Configuration of Controller]

As shown in FIG. 3, the controller 30 includes a retrieving unit 305, a selection unit 310, an adjusting unit 315, a process execution unit 320, a memory 325, a first database 330, and a second database 335. The retrieving unit 305 retrieves a result of measuring the kind of the film formed on the rear surface of the wafer W from the measurement unit 15.

The selection unit 310 selects a process recipe that is optimal for the kind of film that is the measurement result, from process recipes stored in the memory 325. The selection unit 310 defines an RF power supplied in the chamber 100 according to the selected process recipe. In addition, the selection unit 310 selects a temperature of the wafer W corresponding to the kind of the film formed on the rear surface of the wafer W, that is, the measurement result, and the power supplied in the chamber 100, from the first database 330.

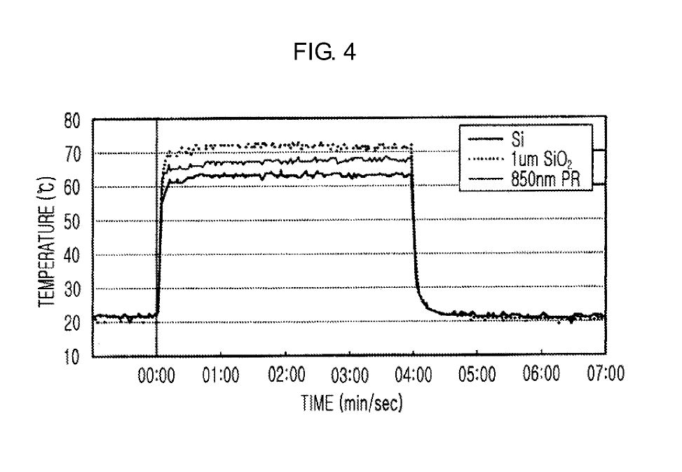

FIG. 4 is a graph showing temperature variation of the wafer W during a plasma process, in cases where the film formed on the rear surface of the wafer W is a silicon (Si) film, a silicon oxide (SiO₂) film, or a photoresist (PR) film. In the present experiment, conditions of the process using the plasma processing apparatus 20 were as follows.

Pressure in the chamber 100: 20 mTorr

Power of RF waves supplied from the radio frequency power source 150: 40 MHz, 1000 W

Power of RF waves supplied from the radio frequency power source 165: 3.2 MHz, 4500 W

Kind of gas and flow rate of gas: C₄F₆ gas/Ar gas/O₂ gas=60/200/70 sccm

Heat transferring gas and pressure: He gas, 15 Torr at the center side of the wafer W, 40 Torr at the edge side of the wafer W

Temperature of lower electrode 110: 20° C.

Under the above conditions, when the plasma process was performed in the parallel flat plate type plasma processing apparatus 20, the temperature of the wafer W varied about 5° C. depending on the silicon (Si) film, the silicon oxide (SiO₂) film, and the photoresist (PR) film, and about 10° C. at the maximum. Through the above result, since thermal resistances on the surface of the electrostatic mechanism 125 and on the rear surface of the wafer W may be different from each other according to the kind of the film formed on the rear surface of the wafer W in a system in which a heat input is performed such as a plasma process, the temperature of the wafer W may become different from a desired value according to the kind of the film formed on the rear surface of the wafer W if a temperature of the coolant, a temperature of the heater 112, and a pressure of the heat transferring gas are only controlled without considering the kind of the film formed on the rear surface of the wafer W. Thus, an excellent processing result may not be obtained.

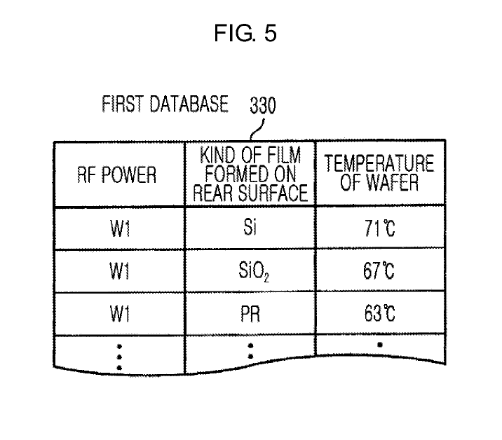

Therefore, according to the present embodiment, the temperature of the wafer W is adjusted in consideration of the kind of the film formed on the rear surface of the wafer W. To do this, in the present embodiment, the first database 330 of FIG. 5 is prepared in advance before performing actual processes.

In the first database 330, an RF power supplied to the chamber 100, kinds of the film formed on the rear surface of the wafer W, and the temperature of the wafer W are stored to be linked to each other. An example of measuring data stored in the first database 330 may be a method of performing plasma processes with respect to a plurality of wafers, having surfaces formed of silicon and different kinds of films on rear surfaces thereof, in the plasma processing apparatus 20, in which a non-contact thermometer such as a low coherence optical-interference thermometer is attached to the susceptor. In more detail, during a process, the RF powers of the radio frequency power source 150 and the radio frequency power source 165, and the temperature of the wafer W at that time are measured by the non-contact thermometer. Measuring results are accumulated in the first database 330 as a data group, in which the RF powers, the kinds of films on the rear surface, and the temperatures of the wafer W are linked to each other. The first database 330 is accommodated in the HDD 36, for example. A detailed example of the non-contact thermometer will be described later.

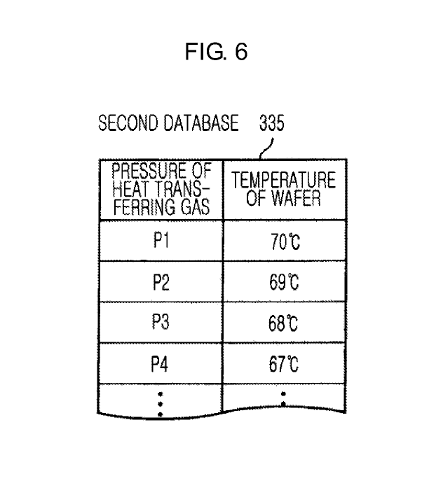

Also, in the present embodiment, the second database 335 of FIG. 6 is prepared in advance before performing actual processes. In the second database 335, the pressure of the heat transferring gas flowing on the rear surface of the wafer W and the temperature of the wafer W are stored to be linked to each other. An example of measuring data stored in the second database 335 is a method of measuring the temperature of the wafer W by using a non-contact thermometer when the pressure of a He gas that is the heat transferring gas is changed during a process under the above processing conditions. Measuring results are stored in the second database 335 as a data group in which the He gas and the temperature of the wafer W are linked to each other. The second database 335 is stored in the HDD 36, for example. The first and second databases 330 and 335 may be integrated as one database.

The selection unit 310 selects the temperature of the wafer W corresponding to the kind of the film formed on the rear surface of the wafer W, that is, the measurement result, and the electric power supplied to process the wafer W from the first database 330. For example, in FIG. 5, in a case where the RF power is W1 and the kind of the film formed on the rear surface is SiO₂, the temperature of the wafer W is selected to be 67° C. In addition, the selection unit 310 selects the pressure of the He gas corresponding to the selected temperature of the wafer W from the second database 335. For example, in FIG. 6, when the selected temperature of the wafer W is 67° C., the pressure of the He gas is P4.

The adjusting unit 315 adjusts the temperature of the wafer W based on the selected temperature of the wafer W. In more detail, the adjusting unit 315 controls a flow rate and the temperature of the coolant that is supplied from the coolant supply source 111, that is, the cooling mechanism, shown in FIG. 2, based on the selected temperature of the wafer W, thereby controlling the AC power supplied from the heater source 113, that is, the heating mechanism.

In addition, the adjusting unit 315 adjusts the He gas flowing on the rear surface of the wafer W based on the selected pressure of the He gas. In detail, the adjusting unit 315 adjusts the He gas supplied from the heat transferring gas supply source 117, that is, the heat transferring gas supply mechanism, based on the selected pressure of the heat transferring gas.

The memory 325 stores a plurality of process recipes. The process execution unit 320 controls an etching process executed in the plasma processing apparatus 20 according to the process recipe that is selected by the selection unit 310 among the plurality of processes recipes. As described above, the cooling mechanism, the heating mechanism, and the heat transferring gas supply mechanism are adjusted by the adjusting unit 315 such that the temperature of the wafer W may be at a desired level according to the kind of the film formed on the rear surface during the process. Accordingly, the temperature of the wafer W may be adjusted with high accuracy.

[Operations of the Plasma Processing Apparatus]

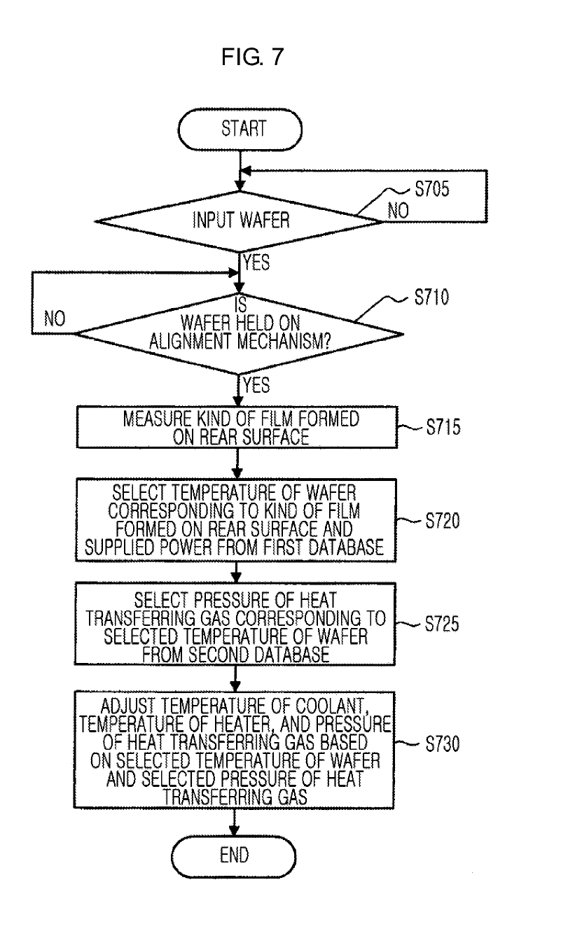

Next, operations of the plasma processing apparatus 20 according to the present embodiment will be described with reference to a flow chart of the temperature controlling method shown in FIG. 7. As a presumption of the temperature controlling method, the first database 330 and the second database 335 are prepared in advance.

In the temperature controlling method, it is determined whether the wafer W is carried in the transfer unit TR from one of the load ports LP1 through LP4 shown in FIG. 1 (S705), and the operation S705 is repeatedly performed until the wafer W is carried in the transfer unit TR. When the wafer W is carried in the transfer unit TR, it is determined whether the wafer W is held on the alignment mechanism AL (S710), and the operation S710 is repeatedly performed until the wafer W is held on the alignment mechanism AL.

When the wafer W is held on the alignment mechanism AL, the measurement unit 15 measures the kind of the film formed on the rear surface of the wafer W (S715). Next, in operation S720, the retrieving unit 305 retrieves the measurement result of the kind of the film formed on the rear surface of the wafer W. The selection unit 310 selects the temperature of the wafer W corresponding to the kind of the film formed on the rear surface and the power of the radio frequency power (RF power) supplied in the plasma processing apparatus 20 from the first database 330.

Next, in operation S725, the selection unit 310 selects the pressure of the heat transferring gas corresponding to the selected temperature of the wafer W from the second database 335. Next, the temperature of the coolant, the temperature of the heater 112, and the pressure of the heat transferring gas provided in the susceptor are adjusted based on the selected temperature of the wafer W and the pressure of the heat transferring gas (S730), and the process is finished.

According to the present embodiment, the temperature of the coolant, the temperature of the heater 112, and the pressure of the heat transferring gas in the susceptor are controlled in consideration of the RF power and the kind of the film formed on the rear surface of the wafer W. Thus, the temperature of the wafer W may be controlled with high accuracy according to whether there is a film on the rear surface and the kind of the film formed on the rear surface. Accordingly, expected processing results, that is, an expected etching process on the wafer W, may be performed.

### Modified Example

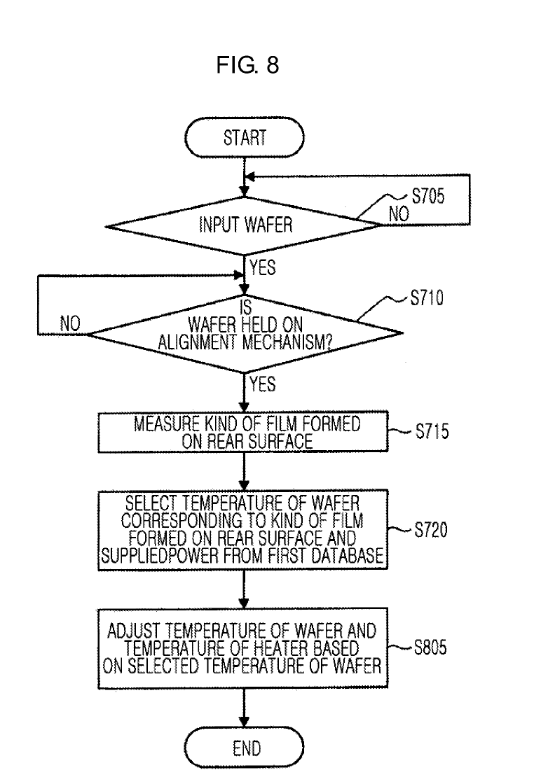

Other apparatuses, in which a heat input is performed, other than the plasma processing apparatus 20, may use the temperature controlling method according to a modified example of the present embodiment. The temperature controlling method according to the present modified example will be described with reference to a flow chart shown in FIG. 8. As a presumption for performing the temperature controlling method according to the present modified example, the first database 330 is prepared in advance; however, the second database 335 is not necessarily prepared.

In the temperature controlling method, it is determined whether the wafer W is carried in the transfer unit TR from one of the load ports LP1 through LP4 shown in FIG. 1 (S705). When the wafer W is carried in the transfer unit TR, it is determined whether the wafer W is held on the alignment mechanism AL or not (S710). When the wafer W is held on the alignment mechanism AL, the measurement unit 15 measures the kind of the film formed on the rear surface of the wafer W (S715). Next, in operation S720, the retrieving unit 305 acquires the measurement result of the kind of the film formed on the rear surface of the wafer W, and the selection unit 310 selects the temperature of the wafer W corresponding to the kind of the film formed on the rear surface and the power of the radio frequency power supplied to the plasma processing apparatus 20 from the first database 330. Next, in operation S805, the temperature of the coolant and the temperature of the heater 112 provided in the susceptor are adjusted based on the selected temperature of the wafer W, and the temperature controlling process is finished.

According to the modified example, the temperature of the coolant and the temperature of the heater 112 in the susceptor are controlled in consideration of the RF power and the kind of the film formed on the rear surface of the wafer W. Thus, the temperature of the wafer W may be controlled with high accuracy according to whether there is a film on the rear surface and the kind of the film formed on the rear surface, in apparatuses other than the plasma processing apparatus 20 where there is a heat input. Accordingly, expected processing results may be obtained.

[Non-Contact Thermometer]

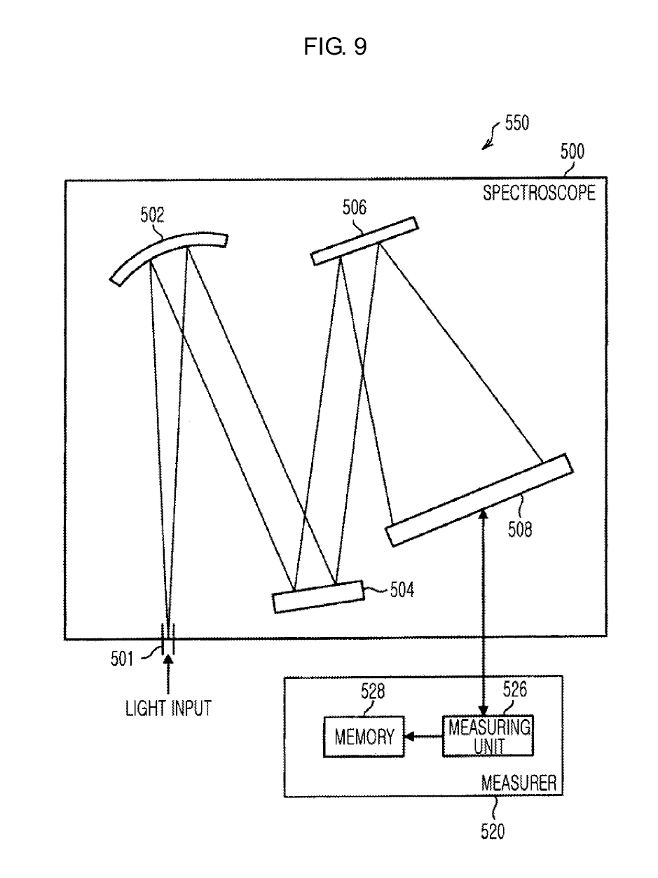

An example of the non-contact thermometer 550 for measuring the temperature of the wafer W will be described with reference to FIG. 9. FIG. 9 is a diagram showing an example of the non-contact thermometer 550 according to the present embodiment.

The non-contact thermometer 550 according to the present embodiment includes a spectroscope 500 and a measurer 520. The spectroscope 500 is a Czerny-Turner type spectroscope that diffracts measuring object light into wavelength units by using a dispersing element, and calculates a light power existing in an arbitrary wavelength width to measure characteristics of the measuring object light from the calculated light power.

The spectroscope 500 includes an input slit 501, a mirror 502, a diffraction grating 504, a mirror 506, and a photo-diode array 508. The mirror 502 and the mirror 506 are provided so as to reflect incident light toward desired directions. The photo-diode array 508 is provided at a location where the light reflected by the mirrors is converged. The light incident from the input slit 501 is light reflected from a front surface and a rear surface of the wafer W having a thickness D, wherein films formed on the rear surface of the wafer W are different from each other. The incident light is reflected by the mirror 502 and irradiated onto the diffraction grating 504. The irradiated light is separated by the diffraction grating 504. Light of a certain wavelength in the reflected light or the diffracted light is reflected by the mirror 506 and is incident to the photo-diode array 508. The photo-diode array 508 detects a power of the incident light. The photo diode array 508 is an example of a detector, in which a plurality of photo detecting devices (photo diodes) for receiving the separated light and detecting the power of the received light are provided as an array. Another example of the detector may be a CCD array.

Each of the devices in the photo diode array 508 generates electric current (photocurrent) according to the power of the received light, and outputs the photocurrent as a detection result of the spectroscope. In addition, each of the devices corresponds to a certain wavelength in advance. In other words, the light is separated into each wavelength by the diffracting grating 504 and the separated light having the certain wavelength corresponding to each of the devices is incident to the photo diode array 508.

The measurer 520 includes a measurement unit 526 and a memory 528. The measurement unit 526 measures characteristics of the incident light based on the detected power of the light. In the present embodiment, the measurement unit 526 measures the temperature of the wafer W from the measurement result based on a frequency analysis of the detected power of the light. The measurement result is stored in the first database 330 or the memory 528.

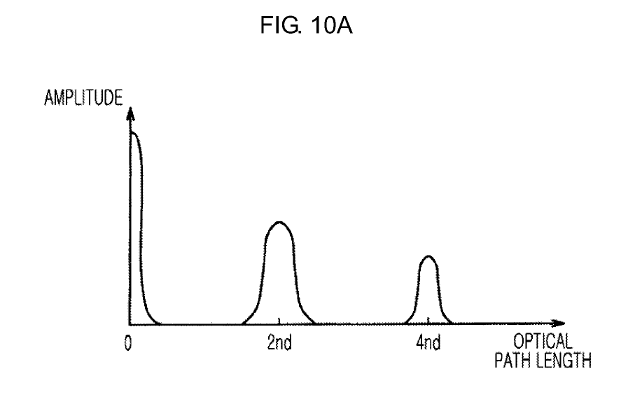

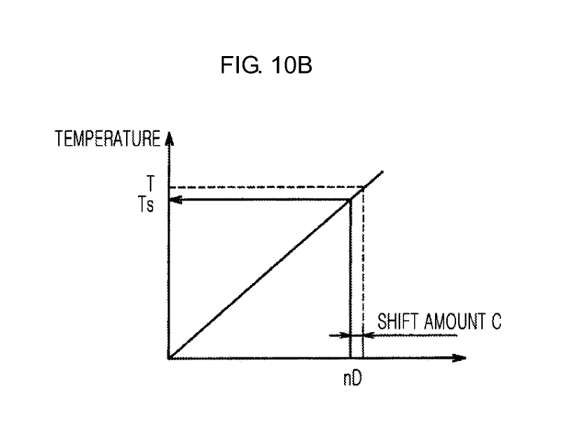

When a fast Fourier transform (FFT) of a reflection spectrum is performed, as shown in FIG. 10A, an optical spectrum of an amplitude is output at locations that are integer number (n) times (n is an integer equal to or greater than 0) a round optical path length (2D) in silicon between a reflected light L1 reflected by the front surface and a reflected light L2 reflected by the rear surface of the wafer W having a thickness D.

As shown in FIG. 10B, a relation between the optical path length nd and the temperature Ts is calculated in advance. Here, when the wafer W is heated, the optical path length D in the wafer W increases due to thermal expansion and a refractive index also increases. Therefore, when the temperature rises, the multiple (nD) of the optical path length D is changed. The temperature T is detected from a shift amount C of the multiple nD of the optical path length D. As such, the temperature of the wafer W for each of the kinds of film formed on the rear surface of the wafer W may be measured from each optical spectrum that is obtained through the FFT of the spectrum data.

In the above embodiment and the modified example, operations of each of the components are related to each other, and thus the operations may be substituted for a series of operations and a series of processes in consideration of the relations between the operations. Accordingly, the embodiment of the temperature controlling method may be an embodiment of the apparatus for executing the temperature controlling method. In the above description, the temperature measuring method of the frequency domain type is described as an example; however, a temperature measuring method of a time domain type (for example, Japanese Laid-open Patent Publication No. 2010-199526) may be used.

While this invention has been particularly shown and described with reference to exemplary embodiments thereof, it will be understood by those skilled in the art that various changes in form and details may be made therein without departing from the spirit and scope of the invention as defined by the appended claims.

For example, the plasma processing apparatus according to the present invention is not limited to the etching apparatus described in the above embodiments, and may be all kinds of plasma processing apparatuses such as a film forming apparatus, a microwave plasma processing apparatus, and the like. In addition, other apparatuses besides the plasma processing apparatus may be applied provided that there is a heat input in the apparatus.

The plasma processing apparatus according to the present invention is not limited to the parallel flat plate type plasma processing apparatus described in the above embodiment, and may be any kind of plasma processing apparatus such as an inductively coupled plasma (ICP) processing apparatus, a microwave plasma processing apparatus, and the like.

As described above, according to the present invention, the temperature controlling method capable of controlling the temperature of a processing object with high accuracy and the plasma processing system may be provided.

What is claimed is:

1. A method of controlling temperature, the method comprising:
retrieving a result of measuring a kind of a film formed on a rear surface of a processing object;
selecting a temperature of the processing object corresponding to an electric power supplied to process the processing object and the kind of the film formed on the rear surface of the processing object, which is the measurement result, from a first database, in which the electric power supplied to a chamber, the kind of the film formed on the rear surface of the processing object, and the temperature of the processing object are stored to be linked to one another; and
adjusting the temperature of the processing object based on the selected temperature of the processing object.

2. The method of claim 1, wherein the adjusting of the temperature of the processing object includes controlling a cooling mechanism and a heating mechanism based on the selected temperature of the processing object.

3. The method of claim 1, wherein the selecting of the temperature of the processing object includes selecting a pressure of a heat transferring gas corresponding to the selected temperature of the processing object from a second database, in which the pressure of the heat transferring gas flowing on the rear surface of the processing object and the temperature of the processing object are stored to be linked to each other, and the adjusting of the temperature includes adjusting the heat transferring gas flowing on the rear surface of the processing object based on the selected pressure of the heat transferring gas.

4. The method of claims 1, further comprising measuring the temperature of the processing object according to the power supplied in the chamber by using a non-contact temperature with respect to the processing objects in which a kind of film formed on the rear surface thereof is different, and accommodating the measured temperature of the processing object in linkage with the kind of the film formed on the rear surface and the power in the first database.

5. A plasma processing system which includes a chamber in which a plasma process is performed on a processing object, the plasma processing system comprising:
a retrieving unit which obtains a result of measuring a kind of a film formed on a rear surface of the processing object;
a selection unit which selects a temperature of the processing object corresponding to an electric power supplied to process the processing object and the kind of the film formed on the rear surface of the processing object, which is the measurement result, from a first database, in which the electric power supplied to a chamber, the kind of the film formed on the rear surface of the processing object, and the temperature of the processing object are stored to be linked to one another; and
an adjusting unit which adjusts the temperature of the processing object based on the selected temperature of the processing object.

6. The plasma processing system of claim 5, further comprising a cooling mechanism and a heating mechanism provided in a susceptor, on which the processing object is held,
wherein the adjusting unit controls the cooling mechanism and the heating mechanism based on the selected temperature of the processing object.

7. The plasma processing system of claim 5, wherein the selection unit selects a pressure of a heat transferring gas corresponding to the selected temperature of the processing object from a second database, in which the pressure of the heat transferring gas flowing on the rear surface of the processing object and the temperature of the processing object are stored to be linked to each other, and the adjusting unit adjusts the heat transferring gas flowing on the rear surface of the processing object based on the selected pressure of the heat transferring gas.

8. The plasma processing system of claim 7, further comprising a heat transferring gas supply mechanism provided in the susceptor, on which the processing object is held, wherein the adjusting unit controls the heat transferring gas supply mechanism based on the selected pressure of the heat transferring gas.

9. The plasma processing system of claim 5, further comprising:
an alignment mechanism which determines a location of the processing object; and
a measurement unit which optically measures the kind of the film formed on the rear surface of the processing object that is held on the alignment mechanism.
